(19) United States
(12) Patent Application Publication
(10) Pub. No.: US 2006/0081286 A1
(43) Pub. Date: Apr. 20, 2006

(54) Solar to electrical energy transduction using the streaming potential

(76) Inventor: Michael Edward Starzak, Vestal, NY (US)

Correspondence Address: Michael E. Starzak, 609 Stonehedge Drive, Vestal, NY, 13850, US

(21) Appl. No.: 10/965,484

(22) Filed: Oct. 14, 2004

(51) Int. Cl. H01L 31/00

(52) U.S. Cl. 136/263; 429/111; 136/251

(57) ABSTRACT

Apparatus and method using solar power driven expansion of an electrolytic solution to force said solution through pores in an insulating plate. The pores' surface has fixed surface charge of one polarity. The velocities of the cations and anions through the pores differ because of the fixed surface charge and this produces an electrical charge separation, the streaming potential, as a source of electrical power. Energy absorption can span the full solar spectrum including infrared, visible and near ultraviolet wavelengths. This light is absorbed and degraded to thermal energy of the electrolytic solution for its expansion using (1) a light absorbing electrode contacting the electrolytic solution, (2) light absorbing molecules in the electrolytic solution or (3) light absorbing molecules in a polymeric matrix within the electrolytic solution. Electrolytic solution, cooled after transducing energy, is returned to the electrolytic solution expansion chamber with a pulsed pump system that maintains the electrolytic solution volume in the expansion chamber and limits expansion flow exclusively to the pores. The electrical potential and current appear between one electrode in the electrolytic solution in the expansion chamber and a second electrode contacting the perforated insulator containing the pores and opposite the working electrolytic solution.

### FIELD OF THE INVENTION

The present invention relates to an apparatus for and a method of generating electricity and, in particular, to a apparatus using solar expansion of an electrolytic fluid to force it through charged pores to generate electrical energy.

### BACKGROUND OF THE INVENTION

Solar energy is the most fundamental source of energy. It produces the gradients responsible for renewable energies such as wind and water and was responsible for production of the organic matter that now constitutes fossil fuel. Chemical conversion of solar energy to electrical energy occurs with biological photosynthesis and with photovoltaic cells. Both operate in a limited range of the solar spectrum. The solar energy to electrical energy invention proposed here is an entirely new method for solar to electrical energy transduction that can utilize the entire solar spectrum. The streaming potential, the electrokinetic phenomenon, utilized for transduction in this invention, has also been used to produce electrical power from wind power (Starzak, U.S. Pat. No. 6,440,600). This invention uses the pressure differential caused by the flow of wind (or water) over a surface containing pores with fixed surface charge. The pressure differential draws electrolytic solution on the opposite side into the pores to produce the charge separation and streaming potential and current. This contrasts with this invention where the expansion of the electrolytic solution by solar heating forces the electrolytic solution through the pores to produce the charge separation, streaming potential and streaming current. Since wind creates a pressure differential to draw electrolytic solution through the pores and electrolyte expansion forces electrolyte solution through the pores, both methods of electrolytic solution flow in pores can be combined into a single unit to tap both renewable energy sources.

The invention is structurally simple and can be constructed in sizes that permit its use on individual buildings or larger energy farms. Its component material can be lightweight to make the invention easy to install and maintain. The component materials are inexpensive and construction is straightforward so that the commercial device can be produced at a competitive retail cost with a short payback period for energy savings.

The invention uses solar energy over an extended wavelength region (visible, infrared and near ultraviolet) to heat an electrolytic solution. The volume increase on heating forces electrolytic solution through pores with fixed surface charge embedded in the pore walls. For example, glass has an intrinsic negative surface charge and pores through a glass plate also have this negative fixed charge. The fixed negative surface charge, for example, draws positive charge into a solution layer near the surface. Since the solution layer with the excess positive charge near the surface moves more slowly than solution layers more distant from the surface, the net flow of all layers produces an electrolytic flow where anions move more rapidly than cations to produce the charge separation in the solution that manifests as the streaming potential. An electrode on the glass surface opposite the electrolytic solution and a second electrode in the electrolytic solution transfer the electrical streaming potential and current to external electrical circuits.

### SUMMARY OF THE INVENTION

The invention absorbs light to heat an electrolytic solution that expands to force the solution through a plate permeated with pores whose walls contain fixed surface charge of a single polarity. The different velocities of electrolytic solution cations and anions in the pores produced by the fixed surface charge in the pore walls produces a charge separation in the solution that manifests as an electrical streaming potential and current. The electrolytic solution that passes through the pores is collected and returned to the expansion reservoir for reuse. The electrical potential and current appear between an electrode in the electrolytic solution and a second electrode where electrolytic solution exits the pores.

In one of its aspects, the present invention comprises an apparatus for generated electrical energy from solar energy. The apparatus comprises a generator and a converter operatively connected to the generator via a first and second electrode.

The generator comprises an insulating plate perforated with pores containing fixed surface charge of one polarity. In one embodiment, the insulating plate is glass and the pores contain an intrinsic negative surface charge. In a second embodiment, the plate is an insulating material with pores that are chemically coated to produce a fixed surface charge of a single polarity. The technology of such charged surface coating is extensively developed in capillary electrophoresis. See, e.g. Altria, “Capillary Electrophoresis Guidebook” or Li, “Capillary Electrophoresis”.

The pores are small to use surface tension to limit the flow of electrolyte under gravity but sufficiently large to allow outlet as the electrolytic solution expands with solar heating. The size and charge of the electrolyte also dictates flow under expansion.

The generator comprises a receptacle containing an electrolytic solution and an absorber for radiant solar energy. The insulating plate completely covers the mouth of the receptacle so that all expanding electrolytic solution must pass through the pores in the insulating, perforated plate. In one embodiment, the receptacle is a chamber in graphite. In this embodiment, the black graphite carbon, which is black because it absorbs over the full visible spectral range, functions as a light absorber, a medium to transfer the absorbed energy to the electrolytic solution and an electrode for the converter. Heated, expanded electrolytic solution passes only through the pores in the insulating plate. In a second embodiment, light absorbing material, e.g. solubilized amorphous carbon, is dissolved in the electrolytic solution and the receptacle has a transparent face to transmit radiant energy directly to the electrolytic solution via the absorbing molecules. The volume of the receptacle is determined by local conditions. A smaller volume receptacle is suitable for clear, sunny regions. A larger receptacle is suitable for cloudier regions where the volume of heated electrolytic solution maintains flow through the pores even when the sun is obscured to give an averaged electrical energy production.

The ions of the electrolytic solution can be metal ions, e.g. sodium cation and chloride anions, or polyvalent ions such as highly charged latex spheres. The choice is predicated on the production of the largest separation of charge for a given pore size and configuration.

In one embodiment, the cooled electrolytic solution that leaves the pores in the insulated plate is collected in a collection receptacle and returned to the solution expansion receptacle. In a slanted orientation, e.g. facing the south on a slanted roof, the cooled electrolytic solution is collected at the lowest point in the collection receptacle and returned to the higher solution expansion receptacle with a pump that is activated when the height of solution in the collection receptacle reaches a threshold. The pump is racheted to maintain the volume in the expansion receptacle and prevent backflow from the expanding solution receptacle to the collection receptacle. The energy to raise the electrolytic solution against gravity is a small percentage of the total energy generated by expansion and is minimized using a pump that is activated only when the collection solution reaches a threshold.

The converter is connected to the generator with two electrodes. The first contacts the electrolytic solution. In one embodiment, a carbon expansion receptacle functions as the electrode. This electrode is electrically isolated from a second electrode that contacts cooled electrolytic solution that has passed through the pores. In one embodiment, this electrode can be conducting, e.g. copper, wire screen bonded to the surface of the perforated insulating plate. The screen can be held in place when the two receptacles sandwich the insulating plate and screen to produce the generator. The second electrode must be electrical insulated from the graphite receptacle in that embodiment.

The current and potential generated using the volume expansion of electrolytic solution through charged pores are illustrated for an electrolytic solution in a receptacle of 1 cm³ where sunlight strikes a surface of 1 cm². The surface contains 100 pores of 0.1 μm diameter each with a surface charge density of 1 charge per 10 nm². Solar radiation of 0.1 w/cm² (Angrist,) strikes the surface and is transferred to the solution with a specific heat of 4.2 J/g/deg to give heating rate of (0.1 J/s/cm²)/4.2 J/g/deg=0.024 deg/s. The temperature gradient of volume expansion (Handbook of Chemistry and Physics) Vβ=0.207×10⁻³ cm³/deg gives the volume expansion per second on 0.1 w illumination (0.024 deg/s)(0.207×10⁻³cm³/deg)=5×10⁻⁶ cm ³/s.

The velocity through the pores is this rate of expansion divided by the entry surface area of the 100 pores of 0.1 nm diameter (7.85×10⁻¹¹ cm²)
[5×10⁻⁶ cm³/s]/[7.85×10⁻¹¹ cm²]=6.4×10⁴ cm/s=6.4×10² m/s

The streaming current is determined by the double layer area swept out per second (velocity through a pore times the circumference of the ring (the pore radius r) times the surface charge density (charge in coulombs per square meter)
iₛₜ=v(m/s) (2πr)σ
σ of 1 charge/10 nm² or 0.014 C/m² gives a streaming current
iₛₜ=6.4×10² m/s 3.14×10⁻⁷ m 0.014 C/m²=0.28×10⁻⁵ C/s
For the 100 pores the total current generated by this square centimeter surface with 100 pores heated with 0.1 W/cm² is 0.28 ma.

The streaming potential is determined from Ohm's law ψₛₜ=iR=i/G where the conductance G in the pores is determined from the electrolyte conductivity κ, the pore area A and the pore length 1 (Starzak) G=κA/l. The streaming potential for each 0.5 nm pore in a 1 mm insulator with the conductivity for a 1M solution of potassium chloride (κ=10.2 Sm⁻¹) is
ψₛₜ=iₛₜ/{[κAₚ]/li}=1.8V
The power from a single pore is (ψi)ₛₜ=(0.28×10⁻⁵A)(1.8V)=0.5×10⁻⁵W

This development provides an estimate. More refined calculations and design permit selection of the pore size that provides the largest surface charge area while limiting energy lost to friction in the pores. Of course, the pore size must be large enough to allow an expansion flow for the electrolytic solution expansion rates given.

### BRIEF DESCRIPTION OF THE DRAWINGS

The foregoing summary, as well as the following detailed description of the preferred embodiment of the present invention, will be better understood when used in conjunction with the accompanying drawings, in which

FIG. 1 is a cutaway front view of an apparatus for generating electrical energy in accordance with the present invention.

FIG. 2 is a perspective drawing of the apparatus of FIG. 1.

### DETAILED DESCRIPTION OF THE PREFERRED EMBODIMENTS

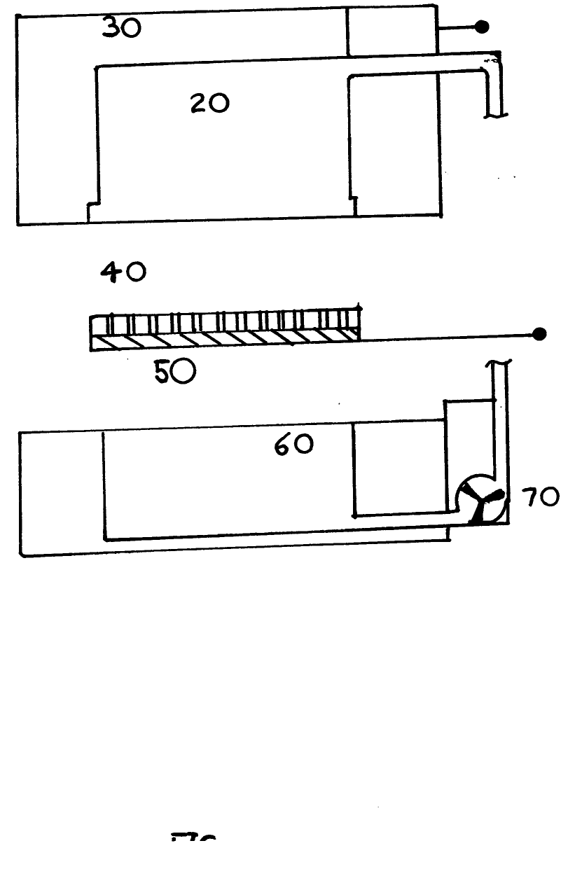

An apparatus for generating electrical energy in accordance with the present invention is designated generally by the numeral 10 in FIG. 1. The apparatus comprises a generator for converting the expansion energy of an electrolytic solution into electrical energy and a converter for converting the electrical potential and current into usable electrical energy.

The generator comprises an upper receptacle or chamber 20 with a light absorbing top plate 30 as an integral part of the receptacle. Alternatively, this top plate is transparent to solar radiation and the light absorbing material is dissolved in the electrolytic solution in expansion receptacle 20. The insulated perforated plate 40 fits snugly into a seat in the electrolyte expansion receptacle 20. A metal conducting screen 50 contacts the insulating perforated plate 40 to function as one electrode for the converter.

The collection receptacle 60 collects the cooled electrolytic solution that has passed through the pores in the insulating plate. A sensor (not shown) monitors solution level in the bottom of the collection receptacle and sends a voltage pulse to rotate the pump vanes 70 to transfer electrolytic solution from the collection receptacle 60 to the expansion receptacle 20 to maintain the volume of electrolytic solution in the expansion chamber 20. The pump also prevents electrolyte solution expansion back to the collection receptacle 60. The converter includes an electrode 50 between the insulated perforated plate 40 and the collection receptacle 60. The second electrode, insulated from the first, can be the conducting graphite expansion receptacle body 30 or an electrode in the electrolytic solution in the expansion chamber (not shown).

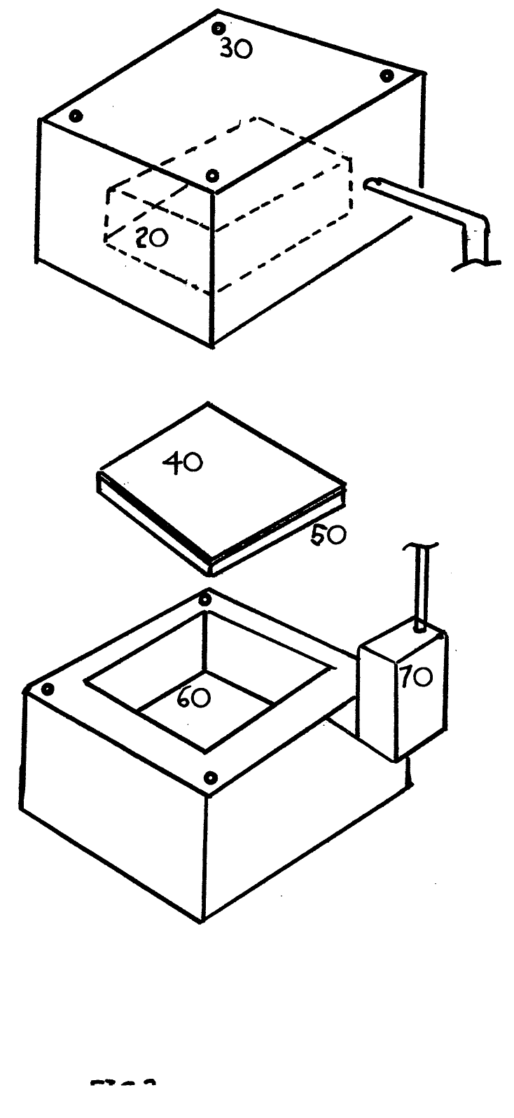

The same embodiment is illustrated as a perspective drawing in FIG. 2. The expansion receptacle 20 is formed in a graphite housing 30. The insulating perforated plate 40 and screen electrode 50 fit snugly into the electrolyte expansion receptacle 20 so that all electrolytic solution expansion drives solution through the pores. The collection chamber 60 is drained by the pump 70 that refills the expansion chamber 20.

The wire screen 50 is one electrode connecting to the converter. The second electrode in this embodiment is the graphite housing of the expansion chamber 20. The region between the graphite electrode/receptacle 20 is electrically insulated to prevent a short circuit between the two electrodes.

It will be recognized by those skilled in the art that changes or modifications may be made to the above described embodiments without departing from the broad inventive concepts of the invention. It should therefore be understood that the invention is not limited to the particular embodiments described herein but is intended to include all changes and modifications that are within the scope and spirit of the invention as set forth in the claims.

What is claimed is:

1. An apparatus for generating electrical energy comprising:
a. a generator comprising:
I) a perforated insulator whose pores contain fixed surface charge of one polarity
ii) means to supply an electrolytic solution to move through these pores
iii) means to absorb solar radiation in the infrared, visible and near ultraviolet range
iii) means to permit expanding electrolytic solution to pass exclusively through these pores
b. a converter comprising:
I) an electrode contacting the electrolytic solution
ii) an electrode contacting the perforated insulator on the side opposite to that contacting the electrolytic solution.

2. The apparatus of claim 1 wherein the means to supply an electrolytic solution to the pores on expansion comprises a sealed receptacle for the electrolytic solution.

3. The apparatus of claim 2 wherein the electrolytic solution receptacle is graphite or other broadband light absorbing material for transfer of light energy to the electrolytic solution.

4. The apparatus of claim 2 wherein the light absorbing material for transfer to the electrolytic solution is dissolved in the electrolytic solution and light enters the solution through a transparent window in the receptacle.

5. The apparatus of claim 2 wherein the light absorbing material is part of a polymeric matrix within the electrolytic solution in the sealed receptacle and light enters the solution through a transparent window in the receptacle.

6. The apparatus of claim 1 where electrolytic solution is collected in a collection receptacle for return to the expansion electrolytic solution.

7. The apparatus of claim 1 wherein the pores in the insulator are intrinsic to the insulator structure.

8. The apparatus of claim 1 wherein the insulator with pores is glass with an intrinsic negative surface charge

9. The apparatus of claim 1 wherein the insulator with pores acquires the proper fixed surface charge by chemical treatment or reaction.

10. The apparatus of claims 2 and 6 with a collection receptacle and pump system that restores electrolytic solution to the receptacle for electrolytic solution expansion while preventing electrolytic solution backflow to the collection receptacle.

11. The apparatus of claim 1 where the porous insulator comprises a parallel array of glass capillaries.

12. The apparatus of claim 1 where the motion of electrolytic solution in the pores with fixed charge is produced by both solar radiation for volume expansion through the pores and wind across the outer surface of the perforated insulator to produce a pressure differential on these pores.
